(19) United States
(12) Patent Application Publication
(10) Pub. No.: US 2022/0259427 A1
(43) Pub. Date: Aug. 18, 2022

(54) RESIN COMPOSITION, LAYERED BODY INCLUDING RESIN COMPOSITION LAYER, LAYERED BODY, AND ELECTROMAGNETIC WAVE SHIELDING FILM

(71) Applicant: TOAGOSEI CO., LTD, Tokyo (JP)

(72) Inventors: Yuya OKIMURA, Nagoya-shi, Aichi (JP); Masahiro TORII, Nagoya-shi, Aichi (JP); Makoto HIRAKAWA, Nagoya-shi, Aichi (JP); Masashi YAMADA, Nagoya-shi, Aichi (JP)

(21) Appl. No.: 17/621,882

(22) PCT Filed: Jun. 23, 2020
(86) PCT No.: PCT/JP2020/024540

§ 371 Date: Dec. 22, 2021

(30) Foreign Application Priority Data
Jun. 28, 2019 (JP) 2019-120891

(51) Int. Cl. C08L 75/06; C08L 23/26; C09D 175/06

(52) U.S. Cl. CPC C08L 75/06; C08L 2205/03; C09D 175/06; C08L 23/26

(57) ABSTRACT

Provided are: a resin composition, containing a polyester polyurethane resin (A), an epoxy resin (B), and a polyolefin resin (C); as well as a layered body including a resin composition layer, a layered body, and an electromagnetic wave shielding film, each using the resin composition.

### TECHNICAL FIELD

The present invention relates to a polyester polyurethane-based resin composition as a material effective for producing a printed wiring board, particularly a flexible printed wiring board or a build-up method multi-layer printed wiring board, which is high in adhesive force to polyimide films or metals, a cured product of which has heat resistance and moist heat resistance, and which is excellent in liquid stability or processability. Further, the present invention relates to a bonding film in which the resin composition is bonded to a release film, a layered body including a resin composition layer in which the resin composition is bonded to a base film, a layered body including a layer that is obtained by curing the resin composition, and an electromagnetic wave shielding film that is bonded to a flexible printed wiring board or the like to be preferably used for shielding electromagnetic noise generated from an electric wiring.

### BACKGROUND ART

Since flexible printed wiring boards can be mounted three-dimensionally and at high density even in a limited space, applications thereof have been expanding. In recent years, along with miniaturization, weight reduction, and the like of electronic devices, related products of flexible printed wiring boards have been diversified, and the demand therefor has been increasing. As such related products, there are flexible copper-clad laminates in which copper foils are affixed to polyimide films, flexible printed wiring boards in which electronic wirings are formed on flexible copper-clad laminates, flexible printed wiring boards including reinforcing plates in which the flexible printed wiring boards and the reinforcing plates are affixed to each other, multilayer plates in which flexible copper-clad laminates or flexible printed wiring boards are layered and joined, and the like. For example, when manufacturing flexible copper-clad laminates, adhesives are usually used to cause polyimide films and copper foils to adhere to each other.

As conventional adhesive compositions or conventional layered bodies, the methods described in Patent Documents 1 to 3 are known.

Patent Document 1 describes a halogen-free flame retardant adhesive composition, characterized by containing a solvent-soluble polyamide resin (A) in a solid state at 25° C., a phenoxy resin (B), an epoxy resin (C) that does not contain a halogen atom, and a phosphorus-based flame retardant (D) that has a structure represented by the following general formula (1), in which the epoxy resin (C) is an epoxy resin that has three or more epoxy groups in one molecule, in which the content of the phenoxy resin (B) is from 100 to 450 parts by mass with respect to 100 parts by mass of the polyamide resin (A), in which the content of the epoxy resin (C) is from 1 to 60 parts by mass with respect to 100 parts by mass in total of the polyamide resin (A) and the phenoxy resin (B), and in which the content of the phosphorus-based flame retardant (D) is from 5 to 100 parts by mass with respect to 100 parts by mass in total of the polyamide resin (A) and the phenoxy resin (B).

Further, Patent Document 2 describes a layered body, characterized in that a curable resin composition is layered on at least one surface of a polyimide-based film, a polyester-based film, or a metal foil, in which the curable resin composition contains a polyester-based polymer (a) that contains two or more carboxyl groups in a molecule, that has a number average molecular weight of from 5,000 to 100,000, and that has a molecular weight per carboxyl group of from 1,500 to 10,000, an epoxy resin (b) that contains two or more epoxy groups in a molecule, and an epoxy resin curing promoter (c), in which the curable resin composition can retain thermoplasticity at 5° C. for a period of 5 months or longer. Patent Document 2 also describes a layered body, in which the curable resin composition of the above-described layered body has been cured to be layered on a metal foil (including a metal wiring).

Further, Patent Document 3 describes a resin composition for an adhesive, the composition containing a polyurethane resin (a) that contains a carboxyl group, that has an acid value (unit: equivalent/10⁶ g) of from 100 to 1,000, that has a number average molecular weight of from 5.0×10³ to 1.0×10⁵, and that has a glass transition temperature of from −10° C. to 70° C., an epoxy resin (b) that contains a nitrogen atom, and an epoxy resin (c) that has a dicyclopentadiene skeleton, in which a formulation ratio of the resin (b) is from 0.1% by mass to 20% by mass with respect to the whole epoxy resin contained in the resin composition.
Patent Document 1: Japanese Patent Publication No. 5846290
Patent Document 2: Japanese Patent Application Laid-Open No. 2005-125724
Patent Document 3: Japanese Patent Application Laid-Open No. 2010-84005

### SUMMARY OF INVENTION

### Technical Problem

An object to be solved by the present invention is to provide a resin composition that is excellent in conductivity even after a long-term (1,000 hours) storage under environment of high temperature and high humidity (85° C., 85% RH).

Another object to be solved by the present invention is to provide a layered body including a resin composition layer, a layered body, or an electromagnetic wave shielding film, each using the resin composition.

### Solution to Problem

Means for solving the problem described above include the following aspects.

<1> A resin composition, including: a polyester polyurethane resin (A); an epoxy resin (B); and a polyolefin resin (C).

<2> The resin composition according to <1>, in which a content of the polyester polyurethane resin (A) is from 10% by mass to 70% by mass, and a content of the polyolefin resin (C) is from 10% by mass to 70% by mass, each with respect to a total amount of a resin solid content except for a filler component.

<3> The resin composition according to <1> or <2>, further including an organic filler (D).

<4> The resin composition according to <3>, including the organic filler (D) in an amount of from 5 parts by mass to 40 parts by mass with respect to a total amount, of 100 parts by mass, of a resin solid content except for a filler component.

<5> The resin composition according to any one of <1> to <4>, in which the epoxy resin (B) includes at least one of a bisphenol type epoxy resin or a bisphenol novolak type epoxy resin.

<6> The resin composition according to any one of <1> to <5>, in which a number average molecular weight of the polyester polyurethane resin (A) is from 10,000 to 80,000, and a molecular weight per urethane bond in the polyester polyurethane resin (A) is from 200 to 8,000.

<7> The resin composition according to any one of <1> to <6>, in which the polyester polyurethane resin (A) includes a polyester polyurethane resin having a polyester structure that has a number average molecular weight of from 8,000 to 30,000.

<8> The resin composition according to any one of <1> to <7>, in which an acid value of the polyester polyurethane resin (A) is from 0.1 mgKOH/g to 20 mgKOH/g.

<9> The resin composition according to any one of <1> to <8>, in which a diol component configuring the polyester polyurethane resin (A) includes a diol having a side chain.

<10> The resin composition according to any one of <1> to <9>, in which the polyolefin resin (C) is a polypropylene-based resin that is graft-modified with a modifier including an α,β-unsaturated carboxylic acid or a derivative thereof, and a content of a graft portion is from 0.1% by mass to 20% by mass with respect to a total mass of the polyolefin resin (C).

<11> The resin composition according to any one of <1> to <10>, further including a metal filler (E).

<12> The resin composition according to <11>, including the metal filler (E) in an amount of from 10 parts by mass to 350 parts by mass with respect to a total amount, of 100 parts by mass, of a resin solid content except for a filler component.

<13> The resin composition according to <11> or <12>, in which the metal filler (E) is a conductive filler.

<14> A layered body including a resin composition layer, the layered body including: a resin composition layer that consists of the resin composition according to any one of <1> to <13>; and a base film that is in contact with at least one surface of the resin composition layer, in which the resin composition layer is in a B-stage state.

<15> A layered body, including a cured layer obtained by curing the resin composition according to any one of <1> to <13>.

<16> An electromagnetic wave shielding film, including a resin composition layer that consists of the resin composition according to any one of <1> to <13>.

### Advantageous Effects of Invention

According to the present invention, it is possible to provide a resin composition that is excellent in conductivity even after a long-term (1,000 hours) storage under environment of high temperature and high humidity (85° C., 85% RH).

Further, according to the present invention, it is possible to provide a layered body including a resin composition layer, a layered body, or an electromagnetic wave shielding film, each using the resin composition.

### DESCRIPTION OF EMBODIMENTS

The explanation of constituent elements described below may be made based on representative embodiments of the present invention, but the present invention is not limited to such embodiments. Herein, the range “(from) X to Y” is used to mean a range that includes the numerical values X and Y described before and after “to” as the lower limit value and the upper limit value, respectively.

In the numerical range described stepwise herein, the upper limit value or the lower limit value described in one numerical range may be replaced with the upper limit value or the lower limit value of another numerical range described stepwise. Further, in the numerical range described herein, the upper limit value or the lower limit value of the numerical range may be replaced with the value indicated in the examples.

In the present invention, the amount of each component in the composition means, when multiple substances corresponding to each component are present in the composition, the total amount of the multiple substances that are present in the composition, unless otherwise specified.

In the present invention, the term “step” includes not only an independent step, but also a step that is not clearly distinguished from another step but that achieves the intended purpose of the step.

In the present invention, “% by mass” and “% by weight” are synonymous, and “parts by mass” and “parts by weight” are synonymous.

Further, in the present invention, a combination of two or more preferable embodiments is a more preferable embodiment.

Further, “(meth)acrylic” herein represents both an acrylic and a methacrylic, or either of them.

Further, in the present disclosure, “main chain” represents a relatively longest bonding chain in the molecule of a polymer compound that constitutes a resin, and “side chain” represents a carbon chain that is branched from the main chain.

Furthermore, in some of the compounds herein, a hydrocarbon chain may be expressed by a simplified structural formula that omits the symbols of carbon (C) and hydrogen (H).

Hereinafter, the present invention will be described in detail.

(Resin Composition)

The resin composition of the present invention contains a polyester polyurethane resin (A), an epoxy resin (B), and a polyolefin resin (C).

The resin composition of the present invention can be preferably used as an adhesive composition, can be more preferably used as an adhesive composition for adhesion with polyimides or metals, and can be particularly preferably used as an adhesive composition for adhesion between polyimides and metals.

The present inventors have found that conventional resin compositions are not sufficient in terms of conductivity after a long-term storage under environment of high temperature and high humidity.

The present inventors have found, as a result of intensive studies, that three kinds of resins, accordingly, the polyester polyurethane resin (A), the epoxy resin (B), and the polyolefin resin (C) are contained, by which, although the detailed mechanism is not clear, these three kinds of resins act in concert with each other and complement each other to make it possible to provide a resin composition that is excellent in conductivity even after a long-term storage under environment of high temperature and high humidity.

Further, the resin composition of the present invention is also excellent in adhesiveness and solder heat resistance by containing the three kinds of resins, accordingly, the polyester polyurethane resin (A), the epoxy resin (B), and the polyolefin resin (C).

In particular, the resin composition of the present invention is high in adhesive force with polyimides and metals, excellent in conductivity at initial stage and after soldering, and also excellent in heat resistance by containing the three kinds of resins, accordingly, the polyester polyurethane resin (A), the epoxy resin (B), and the polyolefin resin (C).

Hereinafter, the present invention will be described in detail.

Herein, “polyester polyurethane resin (A)” and the like are also referred to as “component (A)” and the like.

<Polyester Polyurethane Resin (A)>

The resin composition of the present invention contains a polyester polyurethane resin (A).

The polyester polyurethane resin (A) may be a resin having two or more ester bonds and two or more urethane bonds, and is preferably a resin having a polyester chain and two or more urethane bonds.

Further, the polyester polyurethane resin (A) is preferably a resin that is obtained by a reaction of at least a polyester polyol, a polyisocyanate, and a chain extender as raw materials thereof, and is more preferably a resin that is obtained by a reaction of at least a polyester polyol, a polyisocyanate, and a diol compound.

The polyester portion of the polyester polyurethane resin (A) is preferably formed from an acid component and an alcohol component.

As the acid component, a polyvalent carboxylic acid compound is preferable, and a dicarboxylic acid compound is more preferable. Further, as the acid component, a sulfocarboxylic acid compound or the like can also be used. Further, preferred examples of the acid component include an aromatic acid.

As the alcohol component, a polyvalent alcohol compound is preferable, and a diol compound is more preferable.

Further, the polyester portion may be formed from a hydroxycarboxylic acid compound.

When the total amount of the whole acid component configuring the polyester portion of the polyester polyurethane resin (A) is 100 mol %, the aromatic acid is preferably 30 mol % or more, more preferably 45 mol % or more, and particularly preferably 60 mol % or more of the whole acid component, from the viewpoints of adhesiveness, heat resistance, and moist heat resistance.

Examples of the aromatic acid include aromatic dicarboxylic acids, such as terephthalic acid, isophthalic acid, orthophthalic acid, naphthalenedicarboxylic acid, biphenyldicarboxylic acid, and 5-hydroxyisophthalic acid. Also, examples thereof can include: an aromatic dicarboxylic acid having a sulfonic acid group or a sulfonate group, such as sulfoterephthalic acid, 5-sulfoisophthalic acid, 4-sulfophthalic acid, 4-sulfonaphthalene-2,7-dicarboxylic acid, 5-(4-sulfophenoxy)isophthalic acid, sulfoterephthalic acid, a metal salt thereof, and an ammonium salt thereof; and an aromatic oxycarboxylic acid, such as p-hydroxybenzoic acid, p-hydroxyphenylpropionic acid, p-hydroxyphenylacetic acid, 6-hydroxy-2-naphthoic acid, and 4,4-bis(p-hydroxyphenyl)valeric acid. Among these, from the viewpoint of adhesiveness, the acid component preferably includes at least one of terephthalic acid or isophthalic acid, and is particularly preferably at least one of terephthalic acid or isophthalic acid.

Further, the acid component may be a derivative of an acid compound, such as an ester, at the time of resin synthesis.

Other examples of the acid component can include: alicyclic dicarboxylic acids, such as 1,4-cyclohexanedicarboxylic acid, 1,3-cyclohexanedicarboxylic acid, 1,2-cyclohexanedicarboxylic acid and its acid anhydride; and aliphatic dicarboxylic acids, such as succinic acid, adipic acid, azelaic acid, sebacic acid, dodecanedioic acid, and dimer acid.

On the other hand, preferred examples of the polyvalent alcohol component include aliphatic diol compounds, alicyclic diol compounds, aromatic-containing diol compounds, and ether bond-containing diol compounds.

Examples of the aliphatic diol compound can include ethylene glycol, 1,2-propyrenediol, 1,3-propanediol, 1,4-butanediol, 1,5-pentanediol, neopentyl glycol, 1.6-hexanediol, 3-methyl-1,5-pentanediol, 1,9-nonanediol, 2-butyl-2-ethyl-1,3-propanediol, neopentyl glycol hydroxypivalate, dimethylol heptane, and 2,2,4-trimethyl-1,3-pentanediol.

Examples of the alicyclic diol compound can include 1,4-cyclohexanediol, 1,4-cyclohexanedimethanol, tricyclodecanediol, tricyclodecanedimethylol, a spiroglycol, hydrogenated bisphenol A, an ethylene oxide adduct of hydrogenated bisphenol A, and a propylene oxide adduct of hydrogenated bisphenol A.

Examples of the aromatic-containing diol compound can include paraxylene glycol, metaxylene glycol, orthoxylene glycol, 1,4-phenylene glycol, an ethylene oxide adduct of 1,4-phenylene glycol, bisphenol A, and a glycol that is obtained by adding 1 mol to several mols of ethylene oxide or propylene oxide to two phenolic hydroxyl groups of a bisphenol, such as an ethylene oxide adduct of bisphenol A and a propylene oxide adduct of bisphenol A.

Examples of the ether bond-containing diol compound include diethylene glycol, triethylene glycol, dipropylene glycol, polyethylene glycol, polypropylene glycol, polytetramethylene glycol, an ethylene oxide adduct of neopentyl glycol, and a propylene oxide adduct of neopentyl glycol.

Among these diols, a diol having a side chain, such as neopentyl glycol and 2-butyl-2-ethyl-1,3-propanediol, is preferable due to compatibility with epoxy resins, polyolefin resins, or the like and solution stability.

Accordingly, the diol component configuring the polyester polyurethane resin (A) preferably includes a diol having a side chain, from the viewpoints of compatibility with epoxy resins, polyolefin resins, or the like and solution stability.

Above all, from the viewpoints of compatibility with epoxy resins, polyolefin resins, or the like, solution stability, and conductivity, the chain extender configuring the polyester polyurethane resin (A) preferably includes a diol having a side chain. Accordingly, the polyester polyurethane resin (A) is preferably a resin that is obtained by a reaction of at least a polyester polyol, a polyisocyanate, and a diol having a side chain as raw materials thereof, from the viewpoints of compatibility with epoxy resins, polyolefin resins, or the like, solution stability, and conductivity.

In addition, a hydroxycarboxylic acid compound having a hydroxy group and a carboxy group in the molecular structure can also be used as the polyester raw material, examples of which can include 5-hydroxyisophthalic acid, p-hydroxybenzoic acid, p-hydroxyphenethyl alcohol, p-hydroxyphenylpropionic acid, p-hydroxyphenylacetic acid, 6-hydroxy-2-naphthoic acid, and 4,4-bis(p-hydroxyphenyl)valeric acid.

As the component configuring the polyester portion of the polyester polyurethane resin (A), a tri- or higher functional polycarboxylic acid and/or polyol may be further copolymerized at a ratio of from about 0.1 mol % to about 5 mol % with respect to the whole acid component or the whole polyvalent alcohol component that configures the polyester portion, for the purpose of introducing a branched skeleton as needed. In particular, in the case of reacting with a curing agent to obtain a cured layer, introduction of a branched skeleton increases terminal group density (reaction site) of the resin, by which a cured layer that is high in crosslinking density can be obtained. Examples of the tri- or higher functional polycarboxylic acid that can be used in this case include a compound, such as trimellitic acid, trimesic acid, ethyleneglycol bis(anhydrotrimellitate), glycerol tris(anhydrotrimellitate), trimellitic anhydride, pyromellitic anhydride (PMDA), oxydiphthalic dianhydride (ODPA), 3,3′,4,4′-benzophenone tetracarboxylic dianhydride (BTDA), 3,3′,4,4′-diphenyltetracarboxylic dianhydride (BPDA), 3,3′,4,4′-diphenylsulfontetracarboxylic dianhydride (DSDA), 4,4′-(hexafluoroisopropylidene)diphthalic dianhydride (6FDA), and 2,2′-bis[(dicarboxyphenoxy)phenyl]propane dianhydride (BSAA). On the other hand, examples of the tri- or higher functional polyol that can be used include glycerin, trimethylolethane, trimethylolpropane, and pentaerythritol. In the case of using the tri- or higher functional polycarboxylic acid and/or polyol, it may be copolymerized preferably in a range of from 0.1 mol % to 5 mol %, and more preferably in a range of from 0.1 mol % to 3 mol %, with respect to the whole acid component or the whole polyvalent alcohol component.

Acid addition of from about 0.1 mol % to about 10 mol % can be performed with respect to the whole acid component or the whole polyvalent alcohol component that configures the polyester portion, for the purpose of introducing a carboxy group into the polyester portion of the polyester polyurethane resin (A) as needed. Since use of a monocarboxylic acid, a dicarboxylic acid, or a polyfunctional carboxylic acid compound for acid addition causes decrease in molecular weight due to transesterification, it is preferable to use an acid anhydride.

As the acid anhydride, a compound, such as succinic anhydride, maleic anhydride, orthophthalic acid, 2,5-norbomenedicarboxylic anhydride, tetrahydrophthalic anhydride, trimellitic anhydride, pyromellitic anhydride (PMDA), oxydiphthalic dianhydride (ODPA), 3,3′,4,4′-benzophenonetetracarboxylic dianhydride (BTDA), 3,3′,4,4′-diphenyltetracarboxylic dianhydride (BPDA), 3,3′,4,4′-diphenylsulfontetracarboxylic dianhydride (DSDA), 4,4′-(hexafluoroisopropylidene)diphthalic dianhydride (6FDA), and 2,2′-bis[(dicarboxyphenoxy)phenyl]propane dianhydride (BSAA), can be used.

Acid addition can be carried out, after polyester polycondensation, directly in a bulk state or by solubilizing the polyester and carrying out the addition. The reaction in a bulk state progresses quickly. However, when acid addition is carried out in a large amount, gelation may occur and the reaction may progress at a high temperature; therefore, care is required in terms, for example, of blocking oxygen gas to prevent oxidation. On the other hand, the reaction of acid addition in a solution state progresses slowly, but a large amount of carboxy groups can be stably introduced.

The polyisocyanate that is used for producing the polyester polyurethane resin (A) may be: one of a diisocyanate, a dimer thereof (uretdione), a trimer thereof (isocyanurate, triol adduct, burette), or the like; or a mixture of two or more thereof. Examples of the diisocyanate component include 2,4-tolylene diisocyanate, 2,6-tolylene diisocyanate, p-phenylene diisocyanate, diphenylmethane diisocyanate, m-phenylene diisocyanate, hexamethylene diisocyanate, tetramethylene diisocyanate, 3,3′-dimethoxy-4,4′-biphenylene diisocyanate, 1,5-naphthalene diisocyanate, 2,6-naphthalene diisocyanate, 4,4′-diisocyanate diphenyl ether, m-xylylene diisocyanate, 1,3-diisocyanate methylcyclohexane, 1,4-diisocyanate methylcyclohexane, 4,4′-diisocyanate cyclohexane, 4,4′-diisocyanate cyclohexylmethane, isophorone diisocyanate, dimer acid diisocyanate, and norbornene diisocyanate. Among these, an aliphatic or alicyclic diisocyanate is preferable from the viewpoint of transparency. Further, hexamethylene diisocyanate or isophorone diisocyanate is particularly preferable due to availability and economic reasons.

If necessary, a chain extender may be used in producing the polyester polyurethane resin (A).

Examples of the chain extender include: the diol compound described above as a constituent component of the polyester portion; and a compound having one carboxy group and two hydroxy groups, such as dimethylolpropionic acid and dimethylolbutanoic acid.

Among these, from the viewpoint of conductivity, the chain extender is preferably a diol compound, more preferably a diol compound having a side chain, and particularly preferably a diol compound having a branched chain.

From the viewpoint of conductivity, the diol compound having a side chain preferably includes at least one compound selected from the group consisting of neopentyl glycol, 2-butyl-2-ethyl-1,3-propanediol, and 2,2-dimethylolpropionic acid, and particularly preferably includes 2,2-dimethylolpropionic acid and at least one compound selected from the group consisting of neopentyl glycol and 2-butyl-2-ethyl-1,3-propanediol.

The method of producing the polyester polyurethane resin (A) is not particularly limited, and a publically known method can be used. For example, the polyester polyol, the polyisocyanate, and the optional chain extender may be charged collectively or may be charged separately in a reaction vessel. In any case, the reaction is carried out at a ratio of functional group of isocyanate group/hydroxy group of preferably from 0.9 to 1.1, more preferably from 0.98 to 1.02, and particularly preferably 1, which relates to the total hydroxyl value of the polyester polyol and the chain extender, and the entirety of isocyanate groups of the polyisocyanate in the system. Further, this reaction can be carried out under the presence or absence of a solvent that is inert to isocyanate groups, thereby enabling the production. Examples of the solvent include ester-based solvents (such as ethyl acetate, butyl acetate, ethyl butyrate), ether-based solvents (such as dioxane, tetrahydrofuran, diethyl ether), ketone-based solvents (such as cyclohexanone, methyl ethyl ketone, methyl isobutyl ketone), aromatic hydrocarbon-based solvents (such as benzene, toluene, xylene), and mixed solvents thereof, and ethyl acetate or methyl ethyl ketone is preferable from the viewpoint of reduction in environmental load. The reaction apparatus is not limited to a reaction can equipped with a stirring apparatus, and a mixing-kneading apparatus such as a kneader or a twin-screw extruder can also be used therefor.

In order to promote the urethane reaction, it is possible to use a catalyst that is used in ordinary urethane reactions, examples of which include tin-based catalysts (such as trimethyltin laurate, dimethyltin dilaurate, trimethyltin hydroxide, dimethyltin dihydroxide, stannous octoate), lead-based catalysts (such as lead oleate, lead-2-ethylhexoate), and amine-based catalysts (such as triethylamine, tributylamine, morpholine, diazabicyclooctane, diazabicycloundecene).

The glass transition temperature (Tg) of the polyester portion of the polyester polyurethane resin (A) is preferably from 40° C. to 150° C., more preferably from 45° C. to 120° C., further preferably from 50° C. to 90° C., and particularly preferably from 60° C. to 70° C., from the viewpoints of adhesiveness, conductivity, and heat resistance.

Further, the glass transition temperature (Tg) of the polyester polyurethane resin (A) is preferably from 30° C. to 150° C., more preferably from 40° C. to 140° C., and particularly preferably from 50° C. to 120° C., from the viewpoints of adhesiveness, conductivity, and heat resistance.

The number average molecular weight (Mn) of the polyester polyurethane resin (A) is preferably from 5,000 to 100,000, more preferably from 10,000 to 80,000, further preferably from 20,000 to 60,000, and particularly preferably from 25,000 to 50,000, from the viewpoints of conductivity and heat resistance.

The values of the number average molecular weight (Mn) and the weight average molecular weight (Mw) of the resin in the present invention can be obtained by gel permeation chromatography (GPC), respectively.

The molecular weight per urethane bond in the polyester polyurethane resin (A) is preferably from 100 to 15,000, more preferably from 200 to 8,000, and particularly preferably from 300 to 2,000, from the viewpoints of conductivity and heat resistance.

The acid value of the polyester polyurethane resin (A) is preferably from 0 mgKOH/g to 50 mgKOH/g, more preferably from 0.1 mgKOH/g to 20 mgKOH/g, further preferably from 0.1 mgKOH/g to 5 mgKOH/g, and particularly preferably from 1.0 mgKOH/g to 5.0 mgKOH/g, from the viewpoints of adhesiveness and conductivity.

The acid value of the polyester polyurethane resin (A) is preferably from 20 mgKOH/g or less, and particularly preferably 5 mgKOH/g or less, from the viewpoint of heat resistance.

The acid value of the resin in the present invention is determined by a measurement method of neutralization titration of a sample with a potassium hydroxide benzyl alcohol solution using a phenolphthalein solution as an indicator.

Among these, the polyester polyurethane resin (A) has a polyester structure of which number average molecular weight is preferably of from 1,000 to 50,000, more preferably from 2,000 to 40,000, further preferably from 3,000 to 30,000, and particularly preferably from 8,000 to 30,000, from the viewpoints of adhesiveness, conductivity, and heat resistance.

The resin composition of the present invention may contain the polyester polyurethane resin (A) singly or in combination of two or more thereof.

The content of the polyester polyurethane resin (A) is preferably from 5% by mass to 90% by mass, more preferably from 10% by mass to 70% by mass, and particularly preferably from 30% by mass to 70% by mass, with respect to a total amount of a resin solid content except for a filler component in the resin composition, from the viewpoints of adhesiveness, conductivity, and heat resistance.

The resin solid content except for a filler component refers to a resin component (the polyester polyurethane resin (A), the epoxy resin (B), the polyolefin resin (C), or the like) and a curing promoter described later that are non-volatile components from which an organic filler (D), a metal filler (E), and an inorganic filler other than the metal filler (E), each described later, have been removed. The resin component and the curing promoter each may be solid or liquid at an ambient temperature (25° C.).

It is preferable that the content of the polyester polyurethane resin (A) is from 10% by mass to 70% by mass and the content of the polyolefin resin (C) is from 10% by mass to 70% by mass, each with respect to a total amount of a resin solid content except for a filler component in the resin composition of the present invention, from the viewpoints of adhesiveness, conductivity, and heat resistance.

<Epoxy Resin (B)>

The resin composition of the present invention contains an epoxy resin (B).

The epoxy resin (B) is a component that imparts adhesiveness, heat resistance to a cured portion after adhesion, and the like. The epoxy resin (B) in the present invention encompasses not only a polymer compound that has an epoxy group but also a low molecule compound that has an epoxy group. The number of epoxy group in the epoxy resin (B) is preferably 2 or more.

Examples of the epoxy resin (B) include: glycidyl esters, such as orthophthalic acid diglycidyl ester, isophthalic acid diglycidyl ester, terephthalic acid diglycidyl ester, p-hydroxybenzoic acid diglycidyl ester, tetrahydrophthalic acid diglycidyl ester, succinic acid diglycidyl ester, adipic acid diglycidyl ester, sebacic acid diglycidyl ester, trimellitic acid triglycidyl ester; glycidyl ethers, such as a diglycidyl ether of bisphenol A and an oligomer thereof, ethylene glycol diglycidyl ether, propylene glycol diglycidyl ether, 1,4-butanediol diglycidyl ether, 1,6-hexanediol diglycidyl ether, trimethylolpropane triglycidyl ether, pentaerythritol tetraglycidyl ether, tetraphenyl glycidyl ether ethane, triphenyl glycidyl ether ethane, a polyglycidyl ether of sorbitol, a polyglycidyl ether of polyglycerol; novolac type epoxy resins, such as a phenol novolac epoxy resin, an o-cresol novolak epoxy resin, a bisphenol A novolak epoxy resin.

Further, a brominated bisphenol A type epoxy resin to which flame-retardance is imparted, a phosphorus-containing epoxy resin, a dicyclopentadiene skeleton-containing epoxy resin, a naphthalene skeleton-containing epoxy resin, an anthracene type epoxy resin, a tertiary butyl catechol type epoxy resin, a biphenyl type epoxy resin, a bisphenol S type epoxy resin, and the like can also be used.

Among these, the epoxy resin (B) preferably includes at least one of a bisphenol type epoxy resin or a novolak type epoxy resin, and more preferably includes a bisphenol type epoxy resin and a phenol novolak type epoxy resin, from the viewpoints of adhesiveness and heat resistance.

In the present invention, the epoxy resin (B) preferably includes a compound that has three or more epoxy groups in one molecule, in order to achieve high heat resistance after curing. When such a compound is used, cross-linking reactivity with the polyester polyurethane resin (A) and the polyolefin resin (C) is higher than the case of using an epoxy resin that has two epoxy groups, resulting in that sufficient heat resistance can be obtained.

The content of the compound that has three or more epoxy groups in one molecule in the epoxy resin (B) is preferably 15% by mass or more, more preferably 20% by mass or more, and particularly preferably 25% by mass or more, with respect to the total mass of the epoxy resin (B), from the viewpoint of heat resistance.

The resin composition of the present invention may contain the epoxy resin (B) singly or in combination of two or more thereof.

The content of the epoxy resin (B) is preferably from 1% by mass to 60% by mass, more preferably from 2% by mass to 50% by mass, further preferably from 3% by mass to 35% by mass, and particularly preferably from 3% by mass to 20% by mass, with respect to a total amount of a resin solid content except for a filler component in the resin composition, from the viewpoints of adhesiveness, conductivity, and heat resistance.

<Polyolefin Resin (C)>

The resin composition of the present invention contains a polyolefin resin (C).

The polyolefin resin (C) is preferably solid at 25° C.

The polyolefin resin (C) is not particularly limited, and is preferably a modified polyolefin resin, more preferably a modified polyolefin resin having an acid group, and particularly preferably a modified polyolefin resin having a carboxy group.

The polyolefin resin (C) is not particularly limited as long as it has a constituent unit that is derived from an olefin, and a homopolymer or copolymer of an olefin that has 2 or more and 20 or less carbon atoms, such as ethylene, propylene, butene, pentene, hexene, heptene, octene, 4-methyl-1-pentene, is preferably used therefor.

In the present invention, a homopolymer or copolymer of an olefin that has 2 or more and 6 or less carbon atoms is particularly preferable. The content ratio of the constituent unit in the polyolefin resin can be arbitrarily selected and, in the case of bonding to a poorly adhesive adherend, the modified polyolefin resin is preferably a modified resin of an ethylene-propylene copolymer, a propylene-butene copolymer, or an ethylene-propylene-butene copolymer. From the viewpoint of adhesiveness, it is preferable to use a polyolefin resin that has a content ratio of propylene unit of 50 mol % or more and 98 mol % or less. When the content ratio of propylene unit is within the range above, flexibility can be imparted to a bonded portion after two members are bonded to each other.

The weight average molecular weight (Mw) of the polyolefin resin (C) is preferably from 30,000 to 250.000, and more preferably from 50,000 to 200,000. When the weight average molecular weight (Mw) of the polyolefin resin (C) is in the range above, it is possible to obtain a resin composition that is excellent in solubility in a solvent and adhesiveness to an adherend.

Further, these can also be preferably used as an unmodified polyolefin resin that is a raw material of the modified polyolefin resin.

The modified polyolefin resin is preferably a resin having a portion that is derived from an unmodified polyolefin resin and a graft portion that is derived from a modifier, and more preferably that obtained by graft-polymerizing, under the presence of an unmodified polyolefin resin, a modifier that includes an α,β-unsaturated carboxylic acid or a derivative thereof.

The production of the modified polyolefin resin by graft polymerization can be performed by a publically known method, and a radical initiator may be used in the production.

Examples of the method of producing the modified polyolefin resin includes a solution method in which an unmodified polyolefin resin is heated and dissolved in a solvent such as toluene, and the modifier and the radical initiator are added thereto, and a melting method in which an unmodified polyolefin resin, a modifier, and a radical initiator are melt-kneaded using a banbury mixer, a kneader, an extruder, or the like. The way of using the unmodified polyolefin resin, the modifier, and the radical initiator is not particularly limited, and these may be added collectively to the reaction system or may be added sequentially to the reaction system.

In the case of producing the modified polyolefin resin, it is possible to use a modification aid for improving graft efficiency of an α,β-unsaturated carboxylic acid, a stabilizer for adjusting resin stability, and the like.

The modifier includes an α,β-unsaturated carboxylic acid and a derivative thereof. Examples of the α,β-unsaturated carboxylic acid include maleic acid, fumaric acid, tetrahydrophthalic acid, itaconic acid, citraconic acid, crotonic acid, aconitic acid, and norbomenedicarboxylic acid. Examples of the derivative of an unsaturated polycarboxylic acid include an acid anhydride, an acid halide, an amide, an imide, and an ester.

As the modifier, itaconic anhydride, maleic anhydride, aconitic anhydride, and citraconic anhydride are preferable, and itaconic anhydride and maleic anhydride are particularly preferable, from the viewpoint of adhesiveness. In the case of using the modifier, it may be one or more selected from an α,β-unsaturated carboxylic acid or a derivative thereof, and can be a combination of one or more α,β-unsaturated carboxylic acids and one or more derivatives thereof, a combination of two or more α,β-unsaturated carboxylic acids, or a combination of two or more derivatives of α,β-unsaturated carboxylic acids.

The modifier used in the present invention may include other compounds (other modifiers) in addition to the α,β-unsaturated carboxylic acid and the like, depending on the intended purpose.

Examples of other compounds (other modifiers) include a (meth)acrylic acid ester represented by the following formula (1), (meth)acrylic acid, other (meth)acrylic acid derivative, an aromatic vinyl compound, and cyclohexyl vinyl ether. These other compounds may be used singly or in combination of two or more thereof.

CH₂═CR^{A1}COOR^{A2} (1)

(In the formula, R^{A1} is a hydrogen atom or a methyl group, and R^{A2} is a hydrocarbon group.)

In the formula (1), R^{A1} is preferably a methyl group. Further. R^{A2} is preferably an alkyl group having 8 to 18 carbon atoms.

Examples of the compound represented by the formula (1) include methyl (meth)acrylate, ethyl (meth)acrylate, propyl (meth)acrylate, butyl (meth)acrylate, pentyl (meth)acrylate, hexyl (meth)acrylate, heptyl (meth)acrylate, octyl (meth)acrylate, decyl (meth)acrylate, lauryl (meth)acrylate, tridecyl (meth)acrylate, stearyl (meth)acrylate, cyclohexyl (meth)acrylate, and benzyl (meth)acrylate. These compounds may be used singly or in combination of two or more thereof. In the present invention, since heat-resistant adhesiveness is improved, it is preferable to use a modifier that further includes a (meth)acrylic acid ester having an alkyl group having 8 to 18 carbon atoms and, in particular, it is preferable to include octyl (meth)acrylate, lauryl (meth)acrylate, tridecyl (meth)acrylate, or stearyl (meth)acrylate.

Examples of a (meth)acrylic acid derivative other than the (meth)acrylic acid ester include hydroxyethyl (meth)acrylate, glycidyl (meth)acrylate, and an isocyanate-containing (meth)acrylic acid.

Examples of the aromatic vinyl compound include styrene, o-methylstyrene, p-methylstyrene, and α-methylstyrene.

By using, as the modifier, an α,β-unsaturated carboxylic acid or a derivative thereof in combination with other modifier, the graft ratio by the modifier can be improved, the solubility in a solvent can be improved, or the adhesiveness can be improved. In the case of using other modifier except for the (meth)acrylic acid ester represented by the formula (1) above, it is preferable that the usage amount thereof does not exceed the total usage amount of the α,β-unsaturated carboxylic acid, the derivative thereof, and the (meth)acrylic acid ester.

As described above, the modified polyolefin resin preferably has at least a graft portion that is derived from the modifier. Hereinafter, the content ratio of the graft portion (hereinafter, also referred to as “graft mass”) that is contained in the modified polyolefin resin will be described.

The modified polyolefin resin preferably has a graft portion that is derived from an α,β-unsaturated carboxylic acid or a derivative thereof. In the modified polyolefin resin, the graft mass of the graft portion that is derived from an α,β-unsaturated carboxylic acid or a derivative thereof is preferably from 0.1% by mass to 20% by mass and more preferably from 0.2% by mass to 18% by mass, with respect to 100% by mass of the modified polyolefin resin from the viewpoint of adhesiveness. When the graft mass is 0.1% by mass or more, the solubility in a solvent is excellent, and the adhesiveness to an adherend made of a metal or the like is particularly excellent. Further, when the graft mass is 20% by mass or less, sufficient adhesiveness to an adherend made of a resin or the like can be obtained.

The graft mass that is derived from an α,β-unsaturated carboxylic acid or a derivative thereof in the modified polyolefin resin can be determined by an alkali titration method. In the case in which the derivative of an α,β-unsaturated carboxylic acid is an imide or the like that has no acid group, the graft mass can be determined by Fourier transform infrared spectroscopy.

When the modified polyolefin resin includes a graft portion that is derived from the (meth)acrylic acid ester represented by the formula (1), the graft mass thereof is preferably from 0.1% by mass to 30% by mass and more preferably from 0.3% by mass to 25% by mass, with respect to 100% by mass of the modified polyolefin resin. When the graft mass is from 0.1% by mass to 30% by mass, the solubility in a solvent is excellent, the compatibility with other resins or elastomers described later in the case of including these resins or elastomers is excellent, and the adhesiveness to an adherend can be further improved.

When the modifier includes the (meth)acrylic acid ester represented by the formula (1), the graft mass in the obtained modified polyolefin resin can be determined by Fourier transform infrared spectroscopy.

The radical initiator that is used in the production of the modified polyolefin resin can be appropriately selected from those publically known, and for example, it is preferable to use an organic peroxide such as benzoyl peroxide, dicumyl peroxide, lauroyl peroxide, di-t-butyl peroxide, 2,5-dimethyl-2,5-di(t-butylperoxy)hexane, and cumenehydroperoxide.

Examples of the modification aid that can be used in the production of the modified polyolefin resin include divinylbenzene, hexadiene, and dicyclopentadiene. Examples of the stabilizer include hydroquinone, benzoquinone, and a nitrosophenylhydroxy compound.

The weight average molecular weight (Mw) of the polyolefin resin (C) is preferably from 10,000 to 300,000, more preferably from 30,000 to 250,000, and particularly preferably from 50,000 to 200,000, from the viewpoints of solubility, adhesiveness, and solvent resistance after curing.

The acid value of the modified polyolefin resin is preferably from 0.1 mgKOH/g to 50 mgKOH/g, more preferably from 0.5 mgKOH/g to 40 mgKOH/g, and further preferably from 1.0 mgKOH/g to 30 mgKOH/g, from the viewpoints of stability over time, adhesiveness, and solder reflowability of the resin composition.

The resin composition of the present invention may contain the polyolefin resin (C) singly or in combination of two or more thereof.

The content of the polyolefin resin (C) is preferably from 5% by mass to 90% by mass, more preferably from 10% by mass to 70% by mass, and particularly preferably from 30% by mass to 70% by mass, with respect to a total amount of a resin solid content except for a filler component in the resin composition from the viewpoints of adhesiveness, conductivity, and heat resistance.

Further, the contents of the polyester polyurethane resin (A) and the polyolefin resin (C) in the resin composition are preferably from 50% by mass to 98% by mass, more preferably from 70% by mass to 97% by mass, and particularly preferably from 75% by mass to 95% by mass, with respect to a total amount of a resin solid content except for a filler component from the viewpoints of adhesiveness, conductivity, and heat resistance.

<Organic Filler (D)>

The resin composition of the present invention preferably contains an organic filler (D), from the viewpoints of elongation, conductivity, and moist heat resistance of a resulting cured product.

Examples of the organic filler (D) include (meth)acrylic resin particles, polybutadiene particles, nylon particles, polyolefin particles, polyester particles, polycarbonate particles, polyvinyl alcohol particles, polyvinyl ether particles, polyvinyl butyral particles, silicone rubber particles, polyurethane particles, phenolic resin particles, and polytetrafluorinated ethylene particles.

The present inventors have been found that, when the organic filler is mixed with the polyester polyurethane resin (A), the epoxy resin (B), and the polyolefin resin (C), the organic filler has an effect of further enhancing the compatibility of these resins.

Further, from the viewpoint of further improving the compatibility and liquid stability of these resins, silicone particles, polybutadiene particles, (meth)acrylic resin particles, or polyurethane particles are particularly preferable as the organic filler (D).

Further, from the viewpoint of conductivity, (meth)acrylic resin particles or polyurethane particles are preferable.

The average particle diameter of the organic filler (D) is not particularly limited, and is preferably from 0.5 μm to 50 μm, and more preferably from 1 μm to 30 μm, from the viewpoints of coatability and adjustability of coating thickness.

The resin composition of the present invention may contain the organic filler (D) singly or in combination of two or more thereof.

The content of the organic filler (D) is preferably from 1 parts by mass to 50 parts by mass, more preferably from 5 parts by mass to 40 parts by mass, and particularly preferably from 10 parts by mass to 20 parts by mass, with respect to a total amount, of 100 parts by mass, of a resin solid content except for a filler component in the resin composition, from the viewpoints of adhesiveness, conductivity, and curability.

<Metal Filler (E)>

The resin composition of the present invention preferably contains a metal filler (E), from the viewpoints of conductivity and heat resistance.

The metal filler (E) is preferably a conductive filler, and more preferably metal particles made of a conductive metal such as gold, platinum, silver, copper, and nickel, or an alloy thereof, from the viewpoints of conductivity and heat resistance. Instead of particles having a single composition, particles having a metal or a resin as a core, a coating layer of which is formed of a highly conductive material, are also preferable from the viewpoint of cost reduction. The core is preferably made of at least one material selected from the group consisting of nickel, silica, copper, and resin, and is more preferably made of a conductive metal or an alloy thereof. The coating layer is preferably a layer made of a material that is excellent in conductivity, and preferably a layer made of a conductive metal or a conductive polymer.

Examples of the conductive metal include gold, platinum, silver, tin, manganese, indium, and an alloy thereof. Examples of the conductive polymer include polyaniline and polyacetylene. Among these, silver is preferable from the viewpoint of conductivity.

From the viewpoints of cost and conductivity, the particles consisting of the core and the coating layer preferably contain the coating layer at a ratio of from 1 parts by mass to 40 parts by mass, and more preferably contain the coating layer at a ratio of from 5 parts by mass to 30 parts by mass, with respect to 100 parts by mass of the core.

The particles consisting of the core and the coating layer are preferably particles in which the coating layer completely covers the core. However, in actual, a part of the core may be exposed. Even in such a case, if the conductive material covers 70% or more of the surface area of the core, conductivity can be easily maintained.

The shape of the metal filler (E) is not limited as long as the desired conductivity can be obtained. Specifically, for example, a spherical shape, a flake shape, a leaf shape, a dendritic shape, a plate shape, a needle shape, a rod shape, or a botryoid shape is preferable.

The average particle diameter of the metal filler (E) is preferably from 1 μm to 100 μm, more preferably from 3 μm to 50 m, and particularly preferably from 4 μm to 15 sm, from the viewpoints of conductivity and storage stability.

The average particle diameter of particles in the present disclosure is a D50 average particle diameter which is determined by measuring each conductive fine particle powder in a tornado dry powder sample module by means of a laser diffraction/scattering method-particle size distribution measuring device LS 13320 (manufactured by Beckman Coulter), and for which an average of a diameter of particle size at the accumulated value of 50% of the particles is used. The refractive index is set as 1.6.

The average particle diameter of the metal filler (E) can also be determined from an average value of about 20 particles that are randomly selected in the region of an enlarged image (about 1,000× to 10,000× magnification) of an electron microscope. In this case, the average particle diameter is also preferably from 1 μm to 100 μm, and more preferably from 3 μm to 50 μm. If the metal filler (E) has a long axis direction and a short axis direction (for example, rod-shaped particles), the average particle diameter is calculated in terms of length in the long axis direction.

The resin composition of the present invention may contain the metal filler (E) singly or in combination of two or more thereof.

The content of the metal filler (E) is preferably from 1 parts by mass to 500 parts by mass, more preferably from 10 parts by mass to 350 parts by mass, and particularly preferably from 10 parts by mass to 50 parts by mass, with respect to a total amount, of 100 parts by mass, of a resin solid content except for a filler component in the resin composition, from the viewpoints of conductivity, heat resistance, and storage stability.

The resin composition of the present invention may contain an additive other than the components described above.

As the other additive, a thermoplastic resin other than those described above, a tackifier, a flame retardant, a curing agent, a curing promoter, a coupling agent, a heat aging inhibitor, a leveling agent, a defoamer, an inorganic filler, a solvent, or the like can be contained to an extent that the function of the resin composition is not affected.

Examples of the other thermoplastic resin include a phenoxy resin, a polyester resin, a polycarbonate resin, a polyphenylene oxide resin, a polyurethane resin, a polyacetal resin, a polyethylene-based resin, a polypropylene-based resin, and a polyvinyl-based resin. These thermoplastic resins may be used singly or in combination of two or more thereof.

Examples of the tackifier can include a coumarone-inden resin, a terpene resin, a terpene-phenol resin, a rosin resin, a p-t-butylphenol-acetylene resin, a phenol-formaldehyde resin, a xylene-formaldehyde resin, a petroleum hydrocarbon resin, a hydrogenated hydrocarbon resin, and a turpentine resin. These tackifiers may be used singly or in combination of two or more thereof.

The flame retardant may be either an organic flame retardant or an inorganic flame retardant.

Examples of the organic flame retardant include: a phosphorous flame retardant, such as melamine phosphate, melamine polyphosphate, guanidine phosphate, guanidine polyphosphate, ammonium phosphate, ammonium polyphosphate, ammonium phosphate amide, ammonium polyphosphate amide, carbamate phosphate, carbamate polyphosphate, aluminum trisdiethylphosphinate, aluminum trismethylethylphosphinate, aluminum trisdiphenylphosphinate, zinc bisdiethylphosphinate, zinc bismethylethylphosphinate, zinc bisdiphenylphosphinate, titanyl bisdiethylphosphinate, titanium tetrakisdiethylphosphinate, titanyl bismethylethylphosphinate, titanium tetrakismethylethylphosphinate, titanyl bisdiphenylphosphinate, titanium tetrakisdiphenylphosphinate; a nitrogen-based flame retardant, such as a triazine compound (such as melamine, melam, melamine cyanurate), a cyanuric acid compound, an isocyanuric acid compound, a triazole compound, a tetrazole compound, a diazo compound, urea and a silicon-based flame retardant, such as a silicone compound, a silane compound.

Examples of the inorganic flame retardant include a metal hydroxide, such as aluminum hydroxide, magnesium hydroxide, zirconium hydroxide, barium hydroxide, and calcium hydroxide; a metal oxide, such as tin oxide, aluminum oxide, magnesium oxide, zirconium oxide, zinc oxide, molybdenum oxide, and nickel oxide; and zinc carbonate, magnesium carbonate, calcium carbonate, barium carbonate, zinc borate, and hydrated glass.

These flame retardants may be used singly or in combination of two or more thereof.

The curing agent is a component for forming a cross-linked structure by a reaction with the epoxy resin (B), and examples thereof include: an amine-based curing agent, such as an aliphatic diamine, an aliphatic polyamine, a cyclic aliphatic diamine, and an aromatic diamine, a polyamide amine-based curing agent; an acid-based curing agent, such as an aliphatic polyvalent carboxylic acid, an alicyclic polyvalent carboxylic acid, an aromatic polyvalent carboxylic acid, and an acid anhydride thereof; a basic active hydrogen-based curing agent, such as dicyandiamide and an organic acid dihydrazide; a polymercaptan-based curing agent; a novolak resin-based curing agent; a urea resin-based curing agent; and a melamine resin-based curing agent.

These curing agents may be used singly or in combination of two or more thereof.

Examples of the aliphatic diamine-based curing agent include ethylenediamine, 1,3-diaminopropane, 1,4-diaminobutane, hexamethylenediamine, polymethylenediamine, polyetherdiamine, 2,5-dimethylhexamethylenediamine, and trimethylhexamethylenediamine.

Examples of the aliphatic polyanune-based curing agent include diethylenetriamine, iminobis(hexamethylene)triamine, trihexatetramine, tetraethylenepentamine, aminoethylethanolamine, tri(methylamino)hexane, dimethylaminopropylamine, diethylaminopropylamine, and methyliminobispropylamine.

Examples of the cyclic aliphatic diamine-based curing agent include mensendiamine, isophoronediamine, bis(4-amino-3-methyldicyclohexyl)methane, diaminodicyclohexylmethane, bis(aminomethyl)cyclohexane, N-ethylaminopiperazine, 3,9-bis(3-aminopropyl)-2,4,8,10-tetraoxaspiro[5.5]undecane, and a hydrogenated product of m-xylylenediamine.

Examples of the aromatic diamine-based curing agent include m-phenylenediamine, diaminodiphenylmethane, diaminodiphenylsulfone, diaminodiethyldiphenylmethane, and m-xylylenediamine.

Examples of the aliphatic polyvalent carboxylic acid-based curing agent and acid anhydride-based curing agent include succinic acid, adipic acid, dodecenyl succinic anhydride, polyazipic anhydride, polyazelineic anhydride, and polysevacinic anhydride.

Examples of the alicyclic polyvalent carboxylic acid-based curing agent and acid anhydride-based curing agent include methyltetrahydrophthalic acid, methylhexahydrophthalic acid, methylhymic acid, hexahydrophthalic acid, tetrahydrophthalic acid, trialkyltetrahydrophthalic acid, methylcyclodicarboxylic acid, and an acid anhydride thereof.

Examples of the aromatic polyvalent carboxylic acid-based curing agent and acid anhydride-based curing agent include phthalic acid, trimellitic acid, pyromellitic acid, benzophenone tetracarboxylic acid, ethylene glycol glycol bistrimellitic acid, glycerol tristrimellitic acid, and an acid anhydride thereof.

Examples of the polymercaptan-based curing agent include a mercaptoized epoxy resin and a mercaptopropionic acid ester.

Examples of the novolak-based curing agent include a phenol novolac-based curing agent and a cresol novolak-based curing agent.

In the case in which the resin composition of the present invention contains the curing agent, the content of the curing agent is adjusted such that the functional group equivalent thereof is preferably in a range of from 0.2 mole equivalent to 2.5 mole equivalent, and more preferably in a range of from 0.4 mole equivalent to 2.0 mole equivalent, with respect to 1 mole equivalent of epoxy group of the epoxy resin (B), from the viewpoints of adhesiveness and heat resistance.

The curing promoter is a component used for the purpose of promoting the reaction of the epoxy resin (B), and a tertiary amine-based curing promoter, a tertiary amine salt-based curing promoter, an imidazole-based curing promoter, and the like can be used therefor.

These curing promoters may be used singly or in combination of two or more thereof.

Examples of the tertiary amine-based curing promoter include benzyldimethylamine, 2-(dimethylaminomethyl)phenol, 2,4,6-tris(dimethylaminomethyl)phenol, tetramethylguanidine, triethanolamine. N,N′-dimethylpiperazine, triethylenediamine, and 1,8-diazabicyclo[5.4.0]undecene.

Examples of the tertiary amine salt-based curing promoter include: formate, octylate, p-toluenesulfonate, o-phthalate, phenol salt, or phenol novolak resin salt of 1,8-diazabicyclo[5.4.0]undecene; and formate, octylate, p-toluenesulfonate, o-phthalate, phenol salt, or phenol novolac resin salt of 1,5-diazabicyclo[4.3.0]nonene.

Examples of the imidazole-based curing promoter include 2-methylimidazole, 2-undecylimidazole, 2-heptadecylimidazole, 1,2-dimethylimidazole, 2-methyl-4-ethylimidazole, 2-phenylimidazole, 2-phenyl-4-methylimidazole, 1-benzyl-2-methylimidazole, 1-benzyl-2-phenylimidazole, 2,4-diamino-6-[2′-methylimidazolyl-(I′)]-ethyl-s-triazine, 2,4-diamino-6-[2′-undecylimidazolyl-(1′)]-ethyl-s-triazine, 2,4-diamino-6-[2′-ethyl-4′-methylimidazolyl-(1′)]-ethyl-s-triazine, a 2,4-diamino-6-[2′-methylimidazol-(I′)]-ethyl-s-triazine isocyanuric acid adduct, a 2-phenylimidazoleisocyanuric acid adduct, 2-phenyl-4,5-dihydroxymethylimidazole, and 2-phenyl-4-methyl-5-hydroxymethylimidazole.

In the case in which the resin composition of the present invention contains the curing promoter, the content of the curing promoter is preferably from 1 parts by mass to 10 parts by mass, and more preferably from 2 parts by mass to 5 parts by mass, with respect to 100 parts by mass of the epoxy resin (B), from the viewpoints of adhesiveness and heat resistance.

Examples of the coupling agent include: a silane-based coupling agent, such as vinyl trimethoxysilane, 3-glycidoxypropyltrimethoxysilane, p-styryltrimethoxysilane, 3-methacryloxypropylmethyldimethoxysilane, 3-acryloxypropyltrimethoxysilane, N-2-(aminoethyl)-3-aminopropylmethyldimethoxysilane, 3-ureidopropyltriethoxysilane, 3-mercaptopropylmethyldimethoxysilane, bis(triethoxysilylpropyl)tetrasulfide, 3-isocyanatepropyltriethoxysilane, and imidazole silane; a titanate-based coupling agent; an aluminate-based coupling agent; and a zirconium-based coupling agent. These may be used singly or in combination of two or more thereof.

Examples of the heat aging inhibitor include: a phenol-based antioxidant, such as 2,6-di-tert-butyl-4-methylphenol, n-octadecyl-3-(3′,5′-di-tert-butyl-4′-hydroxyphenyl)propionate, and tetrakis[methylene-3-(3,5-di-tert-butyl-4-hydroxyphenyl)propionate]methane; a sulfur-based antioxidant, such as dilauryl-3,3′-thiodipropionate, and dimyristyl-3,3′-dithiopropionate; and a phosphorus-based antioxidant, such as trisnonylphenyl phosphite, and tris(2,4-di-tert-butylphenyl)phosphite. These may be used singly or in combination of two or more thereof.

Examples of the inorganic filler include a powder made of calcium carbonate, titanium oxide, aluminum oxide, zinc oxide, carbon black, talc, silica, or the like. These may be used singly or in combination of two or more thereof.

The resin composition of the present invention can be prepared by mixing the polyester polyurethane resin (A), the epoxy resin (B), the polyolefin resin (C) and, if necessary, the other components.

Since the resin composition of the present invention is preferably used in the state of a solution or a dispersion, it preferably contains a solvent.

Examples of the solvent include: alcohols, such as methanol, ethanol, isopropyl alcohol, n-propyl alcohol, isobutyl alcohol, n-butyl alcohol, benzyl alcohol, ethylene glycol monomethyl ether, propylene glycol monomethyl ether, diethylene glycol monomethyl ether, and diacetone alcohol; ketones, such as acetone, methyl ethyl ketone, methyl isobutyl ketone, methyl amyl ketone, cyclohexanone, and isophorone; aromatic hydrocarbons, such as toluene, xylene, ethylbenzene, mesitylene; esters, such as methyl acetate, ethyl acetate, ethylene glycol monomethyl ether acetate, and 3-methoxybutyl acetate; aliphatic hydrocarbons, such as hexane, heptane, cyclohexane, and methylcyclohexane. These solvents may be used singly or in combination of two or more thereof. When the resin composition of the present invention is in the state of a solution or a dispersion that contains a solvent, coating onto an adherend and formation of a resin composition layer can be facilitated, and a resin composition layer with a desired thickness can be easily obtained.

In the case in which the resin composition of the present invention contains the solvent, the solvent is used such that the solid content concentration is preferably in a range of from 3% by mass to 80% by mass, and more preferably in a range of from 10% by mass to 50% by mass, from the viewpoint of workability or the like that encompasses coating formation ability.

The adherend preferable to the resin composition of the present invention is an object that is made of: a polymer material such as a polyimide resin, a polyetheretherketone resin, a polyphenylene sulfide resin, an aramid resin, and a liquid crystal polymer; a metal material such as copper, aluminum, and stainless, etc. The shape of the adherend is not particularly limited. Two members made of the same materials as or different materials from each other, as adherends, can be adhered each other by the resin composition of the present invention, to produce an integrated composite product. In addition, a product that includes an adhesive resin composition layer, such as a coverlay film and a bonding sheet below, can be produced.

(Layered Body Including Resin Composition Layer and Layered Body)

The layered body including a resin composition layer of the present invention is a layered body including a resin composition layer consisting of the resin composition of the present invention, and preferably includes a resin composition layer consisting of the resin composition of the present invention and a base film that is in contact with at least one surface of the resin composition layer, in which the resin composition layer is in a B-stage state.

In the present invention, that “a resin composition layer is in a B-stage state” means a semi-cured state in which a part of the resin composition layer begins to cure, and the curing of the resin composition layer further progresses by heating or the like.

Further, the resin composition layer consisting of the resin composition of the present invention is, in the case in which a resin composition including a solvent is used, preferably a layer in which at least a part of the solvent has been removed from the resin composition of the present invention.

The layered body of the present invention is preferably a layered body including a cured layer that is obtained by curing a resin composition consisting of the resin composition of the present invention, the layered body including: a cured layer obtained by curing the resin composition of the present invention; and a base film that is in contact with at least one surface of the cured layer.

Each of the layered body including the resin composition layer of the present invention and the layered body of the present invention preferably includes a base material, and more preferably includes, on the base material, a layer consisting of the resin composition of the present invention.

The base material is not particularly limited, and a known base material can be used therefor.

Further, the base material is preferably a film-shaped base material (base film).

The base film is preferably a resin film, more preferably a polyimide film or an aramid film, and particularly preferably a polyimide film.

Neither the polyimide film nor the aramid film is particularly limited as long as it has electrical insulating property, and each of the polyimide film and the aramid film may be a film made of only a polyimide resin or an aramid resin, a film that contains the resin and an additive, or the like, and the side on which the resin composition layer is formed may have been subject to a surface treatment.

The thickness of the base material is not particularly limited, and is preferably from 3 μm to 125 μm.

The thickness of the resin composition layer is preferably from 5 μm to 50 μm, and more preferably from 10 μm to 40 μm.

As the method of producing the layered body including the resin composition layer of the present invention, for example, the resin composition of the present invention including a solvent is applied to the surface of a base film such as a polyimide film to form a resin composition layer, followed by removing at least a part of the solvent from the resin composition layer, by which a layered body including a resin composition layer that is in a B-stage state can be produced.

The drying temperature during removing the solvent is preferably from 40° C. to 250° C. and more preferably from 70° C. to 170° C.

The drying is carried out by passing the layered body applied with the resin composition through a furnace in which hot air drying, far-infrared heating, high-frequency induction heating, and the like are performed.

If necessary, the layered body including the resin composition layer of the present invention may further include a releasable film on the surface of the resin composition layer for storage or the like.

As the releasable film, those known such as a polyethylene terephthalate film, a polyethylene film, a polypropylene film, a silicone releasable paper, a polyolefin resin coated paper, a polymethylpentene (TPX) film, and a fluororesin film are used.

The thickness of the resin composition layer in a B-stage state is preferably from 5 μm to 100 μm, more preferably from 5 μm to 70 μm, further preferably from 5 μm to 50 μm, and particularly preferably from 10 μm to 40 μm.

The thickness of each of the base film and the resin composition layer is selected depending on the application, but the base film tends to be thinner in order to improve electrical characteristics. The preferable thickness of the base film is the same as the preferable thickness of the base material described above.

In the layered body including the resin composition layer of the present invention, the ratio (A/B) of the thickness (A) of the resin composition to the thickness (B) of the base film is preferably from 1 to 10, and more preferably from 1 to 5. Further, it is preferable that the thickness of the resin composition layer is larger than the thickness of the base film.

As the method of producing the layered body of the present invention, for example, the resin composition of the present invention including a solvent is applied to the surface of the base film, drying is then performed in the same manner as in the case of the layered body including the resin composition layer of the present invention, followed by bringing the surface of the resin composition layer formed and an adherend into surface contact with each other and performing laminating, for example, thermal laminating at 80° C. to 150° C. Next, a method in which the layered body (base film/resin composition layer/adherend) is subject to thermal compression bonding and the resin composition layer is then cured by after-cure to form a cured layer is preferable.

The conditions for thermal compression bonding are not particularly limited as long as they enable compression bonding, and can be preferably from 150° C. to 200° C. and a pressure of from 1 MPa to 3 MPa for 1 minute to 60 minutes. The conditions for after-cure are not particularly limited, and can be preferably from 100° C. to 200° C. and from 30 minutes to 4 hours.

The thickness of the cured layer is preferably from 5 μm to 100 μm, more preferably from 5 μm to 70 μm, further preferably from 5 μm to 50 μm, and particularly preferably from 10 μm to 40 μm.

The adherend is not particularly limited, and examples thereof include those described above. Among these, examples preferably include a metal adherend, more preferably include a copper foil and a plated copper foil, and particularly preferably include a gold-plated copper foil.

Further, the shape, size, and the like of the adherend are not particularly limited, and those known can be used.

Further, examples of one embodiment of the layered body of the present invention include a flexible copper-clad laminate.

That is, the flexible copper-clad laminate of the present invention preferably includes a cured layer obtained by curing a resin composition consisting of the resin composition of the present invention, in which a polyimide film or an aramid film, the cured layer obtained by curing the resin composition of the present invention, and a copper foil are layered.

In the flexible copper-clad laminate of the present invention, the cured layer and the copper foil may be formed on both sides of the polyimide film or the aramid film. Since the resin composition of the present invention is excellent in adhesiveness to an object that contains copper, the flexible copper-clad laminate of the present invention is excellent in stability as an integrated product.

The configuration of the polyimide film or the aramid film is the same as that of the polyimide film or the aramid film in the coverlay film of the present invention described above.

The thickness of the cured layer is preferably from 5 μm to 50 μm, and more preferably from 10 μm to 40 μm.

The copper foil is not particularly limited, and electrolytic copper foil, rolled copper foil, or the like can be used therefor.

Further, the copper foil may be plated with a known metal such as gold or silver, or an alloy.

Examples of one embodiment of the layered body including the resin composition layer of the present invention include a bonding film, an electromagnetic wave shielding film, and a coverlay film, which will be described later.

—Bonding Film—

The bonding film of the present invention is a bonding film that includes a resin composition layer consisting of the resin composition of the present invention, and preferably includes a resin composition layer consisting of the resin composition of the present invention and a release film that is in contact with at least one surface of the resin composition layer, in which the resin composition layer is in a B-stage state.

The bonding film of the present invention is also one embodiment of the layered body including a resin composition layer of the present invention, which will be described later.

The bonding film of the present invention may be configured to include a resin composition layer between two releasable films.

As the releasable film, those known as described above are used therefor.

The thickness of the releasable film is preferably from 20 μm to 100 μm.

The thickness of the resin composition layer is preferably from 5 μm to 100 μm, and more preferably from 10 μm to 60 μm.

Examples of the method of producing the bonding sheet of the present invention preferably include a method of applying the resin composition of the present invention including a solvent onto the surface of the releasable film, followed by drying in the same manner as in the case of the layered body including the resin composition layer of the present invention described above.

—Electromagnetic Wave Shielding Film—

The electromagnetic wave shielding film of the present invention includes a resin composition layer that consists of the resin composition of the present invention, and may include a base film or a release film that is in contact with at least one surface of the resin composition layer.

Further, the electromagnetic wave shielding film of the present invention preferably include the resin composition layer and a protective layer.

The protective layer is not particularly limited as long as it is a layer that consists of an insulating resin composition, and any known can be used therefor. Further, the protective layer may use a resin component that is used for the resin composition of the present invention. Further, the protective layer may be formed of two or more layers that are different from each other in terms of composition or hardness.

If necessary, the protective layer may include a curing promoter, a tackifier, an antioxidant, a pigment, a dye, a plasticizer, an ultraviolet absorber, a defoamer, a leveling agent, a filler, a flame retardant, a viscosity adjuster, an anti-blocking agent, or the like.

The thickness of the resin composition layer in the electromagnetic wave shielding film of the present invention is not particularly limited, and is preferably from 3 μm to 30 μm from the viewpoints of conductivity and connectivity with a gland wiring.

Next, the specific embodiment of the method of producing the electromagnetic wave shielding film of the present invention will be described.

Examples thereof can include a method of coating a resin composition for a protective layer onto one surface of a peelable film and drying to form a protective layer, followed by coating the resin composition of the present invention onto the protective layer and drying to form a resin composition layer.

By the production method as exemplified, an electromagnetic wave shielding film in a layered state of resin composition layer/protective layer/peelable film can be obtained.

The method of providing the resin composition layer and the protective layer can be realized by conventionally known coating methods such as gravure coating method, kiss coating method, die coating method, lip coating method, comma coating method, blade coating method, roll coating method, knife coating method, spray coating method, bar coating method, spin coating method, and dip coating method.

The electromagnetic wave shielding film of the present invention can be adhered to a printed wiring board by, for example, a heat press. The resin composition layer is softened by heating and, by pressurization, flows into a gland portion provided on the printed wiring board. As a result, the gland wiring and the conductive adhesive are electrically connected, and the shielding effect can be enhanced.

### EXAMPLES

Hereinafter, the present invention will be more specifically described based on Examples. The present invention is not limited to these Examples. Further, “parts” and “%” indicated below mean “parts by mass” and “% by mass”, respectively, unless otherwise specified.

1. Raw Materials

1-1. Polyester

Commercial products and synthetic products were used as polyesters to be used in the production of polyester polyurethane resins and to be evaluated.

<Commercial Product>

As a commercial product, Aronmelt PES-360HVXM30, manufactured by Toagosei Co. Ltd., was used. Aronmelt PES-360HVXM30 has a number average molecular weight of 20,000.

<Synthesis of Polyester (PES-1)>

In a flask equipped with a stirrer, a nitrogen introduction tube, a distillation tube, and a thermometer, 201 parts by mass of dimethyl terephthalate, 86 parts by mass of ethylene glycol, 140 parts by mass of neopentyl glycol, 0.9 parts by mass of trimethylolpropane, and 0.22 parts by mass of zinc acetate as a catalyst were charged, the temperature was raised while introducing nitrogen to distill off methanol at from 150° C. to 180° C. Then, 183 parts by mass of isophthalic acid, 0.6 parts by mass of trimethylolpropane, and 0.12 parts by mass of antimony trioxide were added, and water was distilled off at from 180° C. to 210° C. Thereafter, while gradually reducing the pressure, the reaction was continued for 6 hours at 230° C. under the reduced pressure of 200 Pa. The obtained polyester resin has a number average molecular weight of 7,000. Then, 180 parts by mass of the synthesized polyester resin was taken, and 378 parts by mass of toluene and 42 parts by mass of methyl isobutyl ketone were added thereto, to prepare a polyester solution (PES-1).

1-2. Polyester Polyurethane Resin

Polyester polyurethane resins a1 to a7 that were obtained by the following methods were used.

(1) Polyester Polyurethane Resin a1

In a flask equipped with a stirrer, a reflux dehydrator, and a distillation tube, 600 parts by mass of PES-360HVXM30, 100 parts by mass of toluene, and 20 parts by mass of neopentyl glycol were charged. After raising the temperature to 120° C. to distill off 100 parts by mass of the solvent containing water, the temperature was lowered to 105° C., and 0.4 parts by mass of 2,2-bis(hydroxymethyl)propionic acid was charged and dissolved therein. Thereafter, 34 parts by mass of hexamethylene diisocyanate was added and, after 30 minutes, 0.2 parts by mass of dimethyl tin dilaurate was added. After continuing the reaction for 6 hours, a solution of polyester polyurethane resin a1 was obtained by diluting with toluene/2-propanol to adjust the solid content concentration to 30%. The number average molecular weight of polyester polyurethane resin a1 was 36,000 and the acid value was 2 mgKOH/g.

(2) Synthesis of Polyester Polyurethane Resins a2 to a7

The synthesis was carried out in the same manner as the synthesis method of polyester polyurethane resin a1, except that the parts by mass of the polyester, the diol, and the diisocyanate were changed to those as shown in Table 1.

TABLE 1

| | | Polyester polyurethane resin | | | | | | |
|---|---|---|---|---|---|---|---|---|
| Parts by mass | | a1 | a2 | a3 | a4 | a5 | a6 | a7 |
| Polyester resin | PES-360HVXM30 | 600 | 600 | 600 | 600 | 600 | — | — |
| | PES-1 | — | — | — | — | — | 600 | 600 |
| Diol | Neopentyl glycol | 20 | — | — | 133 | — | 65 | — |
| component | 2-Butyl-2-ethyl-1,3-propanediol | — | 30 | — | — | — | — | — |
| | 1,4-Butandiol | — | — | — | — | 17 | — | — |
| | 3,3-Dimethylolpropionic acid | 0.4 | 0.4 | 0.5 | 0.5 | 0.4 | 1.4 | 0.4 |

| | | | | | | | |
|---|---|---|---|---|---|---|---|
| Isocyanate component Hexamethylene diisocyanate | 34 | 34 | 3 | 216 | 34 | 106 | 1.5 |
| Glass transition temperature of polyester (° C.) | 65 | 65 | 65 | 65 | 65 | 62 | 62 |
| Number average molecular weight | 36,000 | 35,000 | 32,000 | 40,000 | 40,000 | 15,000 | 9,000 |
| Molecular weight per urethane bond | 920 | 920 | 10,700 | 160 | 1,030 | 380 | 3,000 |
| Acid value (mgKOH/g) | 2 | 2 | 2 | 2 | 2 | 3 | 11 |

The unit of the numerical value in each component column shown in Table 1 is parts by mass.

1-3. Epoxy Resin (B)

The following commercial products were used.

(1) Epoxy Resin b1

Bisphenol A novolak type epoxy resin “EPICLON N-865” (trade name), manufactured by DIC Corporation

(2) Epoxy Resin b2

Bisphenol A type epoxy resin “jER 1055” (trade name), manufactured by Mitsubishi Chemical Corporation

1-4. Polyolefin Resin (C)

(1) Polyolefin Resin c1

100 parts by mass of a propylene-butene random copolymer that was made of 80% by mass of propylene unit and 20% by mass of butene unit, and was produced using a metallocene catalyst as a polymerization catalyst, 1 parts by mass of maleic anhydride, 0.3 parts by mass of lauryl methacrylate, and 0.4 parts by mass of di-t-butyl peroxide were kneaded and reacted using a twin-screw extruder in which the maximum temperature of the cylinder part was set to 170° C. Then, degassing under reduced pressure was performed within the extruder to remove the residual unreacted material, to produce polyolefin resin c1. Polyolefin resin c1 had a weight average molecular weight of 80,000 and an acid value of 10 mgKOH/g. The content ratio of the graft portion in polyolefin resin c1 was 1.5% by mass.

(2) Olefin Resin c2

Using a metallocene catalyst as a polymerization catalyst, 80% by mass of propylene unit and 20% by mass of butene unit were reacted to obtain polyolefin resin c2. Polyolefin resin c2 had a weight average molecular weight of 100,000.

1-5. Organic Filler (D)

(1) Filler d1 Urethane beads “TK-800T” (trade name, average particle diameter 8 μm), manufactured by Negami Kogyo Co., Ltd.

(2) Filler d2

Acrylic beads “J-4P” (trade name, average particle diameter 2.2 μm), manufactured by Negami Kogyo Co., Ltd.

1-6. Metal Filler (E)

Copper powder “FCC-115A” (trade name; in particle size distribution, the amount of particles of 45 μm or less is more than 90% by mass, the amount of particles of from 45 μm to 63 μm is less than 10% by mass, and the amount of particles of from 63 μm to 75 μm is less than 3% by mass), manufactured by Fukuda Metal Foil Powder Industry Co., Ltd.

1-7. Flame Retardant

Aluminum dimethylphosphinate “Exolit OP935” (trade name), manufactured by Clariant

1-8. Curing Promoter

Imidazole-based curing promoter “Curesol C11-Z” (trade name), manufactured by Shikoku Kasei Kogyo Co., Ltd.

1-9. Solvent

A mixed solvent consisting of toluene, methyl isobutyl ketone, 2-propanol, and methylcyclohexane (mass ratio=100:20:20:20)

### Examples 1 to 19 and Comparative Examples 1 to 3

To a flask equipped with a stirrer, the raw materials described above were added at the ratio shown in Table 2, and stirred under heating at 60° C. for 6 hours to dissolve the component (A), the component (B), the component (C), and the curing promoter in the solvent and then disperse the component (D), carbon black, and the flame retardant, thereby producing the liquid adhesive compositions. Thereafter, these all liquid adhesive compositions were used to prepare coverlay films, bonding sheets, and adhesion test pieces A and B, and the evaluations in accordance with (i) to (vi) below were performed.

(1) Preparation of Coverlay Film

The liquid adhesive composition is roll-coated onto the surface of a polyimide film having a thickness of 25 μm so that the thickness after drying was 15 μm, and dried at 120° C. for 2 minutes to obtain a coverlay film that includes an adhesive layer.

(2) Preparation of Adhesion Test Piece A

A gold-plated copper foil with a thickness of 35 μm was prepared. Then, the gold-plated surface was layered so as to be brought into contact with the surface of the adhesive layer of the coverlay film described above, and laminating was performed under the conditions of 150° C., 0.3 MPa. and 1 m/min. The obtained layered body (polyimide film/adhesive layer/gold-plated copper foil) was subject to thermal compression bonding for 5 minutes under the conditions of 150° C. and 3 MPa, and then further underwent after-cure at 160° C. for 2 hours in an oven, by which an adhesion test piece A was obtained.

(3) Preparation of Bonding Sheet

A releasable PET film with a thickness of 35 μm was prepared. Then, the liquid adhesive composition was roll-coated onto the surface thereof so that the thickness after drying was 25 μm, and dried at 140° C. for 2 minutes to obtain a bonding sheet that includes an adhesive layer.

(4) Preparation of Adhesion Test Piece B

A nickel-plated SUS 304 plate with a thickness of 300 μm, and a flexible printed wiring board in which a copper wiring pattern was formed on the surface of a polyimide film with a thickness of 25 μm and a coverlay film with a thickness of 37.5 μm having a through hole with a diameter of 1 mm was layered on the wiring pattern, were prepared. First, the nickel-plated surface of the SUS 304 plate was layered so as to be brought into contact with the surface of the adhesive layer of the bonding sheet described above, and laminating was performed under the conditions of 150° C., 0.3 MPa, and 1 m/min to obtain a layered body (SUS plate/adhesive layer/releasable PET film). Then, the releasable PET film was peeled off, and the flexible printed wiring board (wiring board in which a copper foil wiring was formed on the polyimide film with a thickness of 25 μm and a coverlay film with a thickness of 37.5 μm having a through hole with a diameter of 1 mm was layered on the copper foil wiring) was bonded to the surface of the exposed adhesive layer by thermal compression bonding for 5 minutes under the conditions of 150° C. and 3 MPa, and then further underwent after-cure at 160° C. for 2 hours in an oven, by which an adhesion test piece B (SUS plate/adhesive layer/flexible printed wiring board) was prepared.

(i) Peel Adhesion Strength (Initial)

In order to evaluate the adhesiveness, the 1800 peel adhesion strength (N/mm) when the gold-plated copper foil of each adhesion test piece A was peeled off from the polyimide film under the conditions of the temperature of 23° C. and the tensile speed of 50 mm/min in accordance with JIS C 6481 “Test methods of copper-clad laminates for printed wiring boards” was measured. The width of the adhesion test piece during the measurement was 10 mm.

(ii) Solder Heat Resistance (Peel Adhesion Strength after Soldering Process and Appearance at the Time of Soldering)

The test was conducted under the following conditions in accordance with JIS C 6481.

The adhesion test piece A described above was floated in a solder bath at 260° C. for 60 seconds with the surface of the polyimide film up, and the presence or absence of appearance abnormalities such as swelling or peeling of the adhesive layer was visually evaluated. As a result, those in which appearance abnormalities such as microvoids, swelling, or peeling were not confirmed were indicated as “A”, those in which slight microvoids were observed were indicated as “B”, and those in which appearance abnormalities such as swelling and peeling were confirmed were indicated as “C”. Further, the test piece taken out from the solder bath was measured in terms of 1800 peel adhesion strength (N/cm) when the polyimide film was peeled off from the gold-plated copper foil at 23° C. in accordance with JIS C 6481. The width of the adhesion test piece during the measurement was 10 mm, and the tensile speed was 50 mm/min.

(iii) Flame Retardancy

The coverlay film described above was heat-cured at 160° C. for 2 hours, and the flame retardancy was evaluated in accordance with UL-94. Those that passed the test (VTM-0 class) were indicated as “A”, and those that failed were indicated as “F”.

(iv) Conductivity (Connection Resistance) Initial

The connection resistance value between the SUS plate and the copper foil wiring of the flexible printed wiring board of the adhesion test piece B described above (SUS plate/adhesive layer/flexible printed wiring board) was measured with a resistance value measuring instrument. As a result, those in which the connection resistance value was less than 0.5Ω were indicated as “A”, those in which the connection resistance value was 0.5Ω or more but less than 1Ω were indicated as “B”, those in which the connection resistance value was 1Ω or more but 3Ω or less were indicated as “C”, and those in which the connection resistance value was more than 3Ω were indicated as “D”.

(v) Conductivity (Connection Resistance) after Soldering

The adhesion test piece B described above was floated in a solder bath at 260° C. for 60 seconds. Thereafter, the connection resistance value between the SUS plate and the copper foil wiring of the flexible printed wiring board of the adhesion test piece B taken out from the solder bath was measured with a resistance value measuring instrument. As a result, those in which the connection resistance value was less than 0.5Ω were indicated as “A”, those in which the connection resistance value was 0.5Ω or more but less than 1Ω were indicated as “B”, those in which the connection resistance value was 1Ω or more but 3Ω or less were indicated as “C”, and those in which the connection resistance value was more than 3Ω were indicated as “D”.

(vi) Conductivity (Connection Resistance) after Long-Term Reliability Test

The adhesion test piece B described above was left in a constant temperature and humidity chamber at 85° C. and 85% RH for 1,000 hours. Thereafter, the connection resistance value between the SUS plate and the copper foil wiring of the flexible printed wiring board of the adhesion test piece B was measured with a resistance value measuring instrument. As a result, those in which the connection resistance value was less than 0.5Ω were indicated as “A”, those in which the connection resistance value was 0.5Ω or more but less than 1Ω were indicated as “B”, those in which the connection resistance value was 1Ω or more but 3Ω or less were indicated as “C”, and those in which the connection resistance value was more than 3Ω were indicated as “D”.

(vii) Storage Stability of Adhesive Composition

Each of the adhesive compositions of Examples 1 to 19 and Comparative Examples 1 to 3 having the compositions shown in Table 2 was put in a glass bottle, sealed, stored at 5° C. for a predetermined period, and observed in terms of crystallinity of the composition. Those in which gelation of the adhesive composition or liquid separation was confirmed after storage for the predetermined period were regarded as poor in storage stability and evaluated.

<Evaluation Criteria>

A: 1 week or longer.

F: shorter than 1 week.

TABLE 2

| | | | Examples | | | | | | | |
|---|---|---|---|---|---|---|---|---|---|---|
| | | | 1 | 2 | 3 | 4 | 5 | 6 | 7 | |
| Composition | Polyester | a1 | 50 | 82 | 8 | 50 | 50 | 50 | 50 | |
| of resin | polyurethane | a2 | — | — | — | — | — | — | — | |
| composition | resin (A) | a3 | — | — | — | — | — | — | — | |
| | | a4 | — | — | — | — | — | — | — | |
| | | a5 | — | — | — | — | — | — | — | |
| | | a6 | — | — | — | — | — | — | — | |
| | | a7 | — | — | — | — | — | — | — | |
| | Epoxy | b1 | 5 | 5 | 5 | 5 | 5 | 5 | 5 | |
| | resin (B) | b2 | 5 | 5 | 5 | 5 | 5 | 5 | 5 | |
| | Olefin | c1 | 40 | 8 | 82 | 40 | 40 | 40 | 40 | |
| | resin (C) | c2 | — | — | — | — | — | — | — | |
| | Organic | d1 | — | — | — | 15 | — | 45 | 5 | |
| | filler (D) | d2 | — | — | — | — | 15 | — | — | |
| | Metal filler (E) | | 20 | 20 | 20 | 20 | 20 | 20 | 20 | |
| | Curing promoter | | 1 | 1 | 1 | 1 | 1 | 1 | 1 | |
| | Flame retardant | | 5 | 5 | 5 | 5 | 5 | 5 | 5 | |
| | Solvent (mixed solvent) | | 200 | 200 | 200 | 200 | 200 | 200 | 200 | |
| Evaluation | Peel adhesion | Initial | 5 | 4 | 9 | 5 | 5 | 4 | 5 | |
| result | strength (N/mm) | After | 7 | 6 | 11 | 7 | 7 | 5 | 7 | |
| | | soldering | | | | | | | | |
| | Appearance at the line of | | A | B | A | A | A | A | A | |
| | soldering | | | | | | | | | |
| | Flame retardancy | | A | A | A | A | A | A | A | |
| | Conductivity | Initial | B | B | B | A | A | A | B | |
| | | After | B | C | B | A | A | B | B | |
| | | soldering | | | | | | | | |
| | | After storage | B | C | C | A | B | B | B | |
| | | 85° C./85%/ | | | | | | | | |
| | | 1,000 hrs | | | | | | | | |
| | Storage stability | | A | A | A | A | A | A | A | |
| | | | Examples | | | | | | | |
| | | | 8 | 9 | 10 | 11 | 12 | 13 | 14 | |
| Composition | Polyester | a1 | 50 | — | — | — | — | — | — | |
| of resin | polyurethane | a2 | — | 50 | — | — | — | — | — | |
| composition | resin (A) | a3 | — | — | 50 | — | — | — | — | |
| | | a4 | — | — | — | 50 | — | — | — | |
| | | a5 | — | — | — | — | 50 | — | — | |
| | | a6 | — | — | — | — | — | 50 | — | |
| | | a7 | — | — | — | — | — | — | 50 | |
| | Epoxy | b1 | — | 5 | 5 | 5 | 5 | 5 | 5 | |
| | resin (B) | b2 | 10 | 5 | 5 | 5 | 5 | 5 | 5 | |
| | Olefin | c1 | 40 | 40 | 40 | 40 | 40 | 40 | 40 | |
| | resin (C) | c2 | — | — | — | — | — | — | — | |
| | Organic | d1 | 15 | 15 | 15 | 15 | 15 | 15 | 15 | |
| | filler (D) | d2 | — | — | — | — | — | — | — | |
| | Metal filler (E) | | 20 | 20 | 20 | 20 | 20 | 20 | 20 | |
| | Curing promoter | | 1 | 1 | 1 | 1 | 1 | 1 | 1 | |
| | Flame retardant | | 5 | 5 | 5 | 5 | 5 | 5 | 5 | |
| | Solvent (mixed solvent) | | 200 | 200 | 200 | 200 | 200 | 200 | 200 | |
| Evaluation | Peel adhesion | Initial | 5 | 5 | 4 | 7 | 4 | 5 | 5 | |
| result | strength (N/mm) | After | 7 | 7 | 6 | 9 | 6 | 7 | 7 | |
| | | soldering | | | | | | | | |
| | Appearance at the time of | | A | A | B | A | A | B | B | |
| | soldering | | | | | | | | | |
| | Flame retardancy | | A | A | A | A | A | A | A | |
| | Conductivity | Initial | B | A | C | A | B | C | C | |
| | | After | B | A | C | A | B | C | C | |
| | | soldering | | | | | | | | |
| | | After storage | B | A | C | C | B | C | C | |
| | | 85° C./85%/ | | | | | | | | |
| | | 1,000 hrs | | | | | | | | |
| | Storage stability | | A | A | A | F | F | A | A | |
| | | | | | | | | Comparative | | |
| | | | Examples | | | | | Examples | | |
| | | | 15 | 16 | 17 | 18 | 19 | 1 | 2 | 3 |
| Composition | Polyester | a1 | 50 | 50 | 50 | 8 | 70 | 90 | — | 50 |
| of resin | polyurethane | a2 | — | — | — | — | — | — | — | — |
| composition | resin (A) | a3 | — | — | — | — | — | — | — | — |
| | | a4 | — | — | — | — | — | — | — | — |
| | | a5 | — | — | — | — | — | — | — | — |
| | | a6 | — | — | — | — | — | — | — | — |
| | | a7 | — | — | — | — | — | — | — | — |
| | Epoxy | b1 | 5 | 5 | 5 | 15 | 15 | 5 | 5 | — |
| | resin (B) | b2 | 5 | 5 | 5 | 15 | 15 | 5 | 5 | — |
| | Olefin | c1 | 40 | 40 | — | 70 | 8 | — | 90 | 40 |
| | resin (C) | c2 | — | — | 40 | — | — | — | — | — |
| | Organic | d1 | — | — | 15 | — | — | 10 | 10 | 10 |
| | filler (D) | d2 | — | — | — | — | — | — | — | — |
| | Metal filler (E) | | 9 | 360 | 20 | 20 | 20 | 20 | 20 | 20 |
| | Curing promoter | | 1 | 1 | 1 | 1 | 1 | 1 | 1 | 1 |
| | Flame retardant | | 5 | 5 | 5 | 5 | 5 | 5 | 5 | 5 |
| | Solvent (mixed solvent) | | 200 | 200 | 200 | 200 | 200 | 200 | 200 | 200 |
| Evaluation | Peel adhesion | Initial | 5 | 3 | 3 | 8 | 4 | 2 | 11 | 5 |
| result | strength | After | 7 | 5 | 5 | 9 | 6 | 3 | 13 | 7 |
| | (N/mm) | soldering | | | | | | | | |
| | Appearance at the time of | | A | B | B | A | B | C | A | C |
| | soldering | | | | | | | | | |
| | Flame retardancy | | A | A | A | A | A | A | A | A |
| | Conductivity | Initial | C | B | C | B | B | D | B | D |
| | | After | C | B | C | B | C | D | B | D |
| | | soldering | | | | | | | | |
| | | After | C | B | C | C | C | D | D | D |
| | | storage | | | | | | | | |
| | | 85° C./85%/ | | | | | | | | |
| | | 1,000 hrs | | | | | | | | |

| | | | | | | | | |
|---|---|---|---|---|---|---|---|---|
| Storage stability | A | F | A | A | A | A | A | A |

As is clear from the results shown in Table 2, the resin compositions of Examples 1 to 19 were resin compositions superior in conductivity compared to the resin compositions of Comparative Examples 1 to 3, even after the long-term storage under environment of high temperature and high humidity.

Further, as is clear from the results shown in Table 2, the resin compositions of Examples 1 to 19 were superior in initial adhesiveness and adhesiveness after soldering, and also superior in appearance after soldering formation, and also superior in flame retardancy after curing.

The disclosure of Japanese Patent Application No. 2019-120891, filed Jun. 28, 2019, is incorporated herein by reference in its entirety.

All publications, patent applications, and technical standards described in present specification are herein incorporated by reference to the same extent as if each individual publication, patent application, or technical standard was specifically and individually indicated to be incorporated by reference.

1. A resin composition, comprising:
a polyester polyurethane resin (A);
an epoxy resin (B); and
a polyolefin resin (C).

2. The resin composition according to claim 1, wherein a content of the polyester polyurethane resin (A) is from 10% by mass to 70% by mass, and a content of the polyolefin resin (C) is from 10% by mass to 70% by mass, each with respect to a total amount of a resin solid content except for a filler component.

3. The resin composition according to claim 1, further comprising an organic filler (D).

4. The resin composition according to claim 3, comprising the organic filler (D) in an amount of from 5 parts by mass to 40 parts by mass with respect to a total amount, of 100 parts by mass, of a resin solid content except for a filler component.

5. The resin composition according to claim 1, wherein the epoxy resin (B) comprises at least one of a bisphenol type epoxy resin or a bisphenol novolak type epoxy resin.

6. The resin composition according to claim 1, wherein a number average molecular weight of the polyester polyurethane resin (A) is from 10,000 to 80,000, and a molecular weight per urethane bond in the polyester polyurethane resin (A) is from 200 to 8,000.

7. The resin composition according to claim 1, wherein the polyester polyurethane resin (A) comprises a polyester polyurethane resin having a polyester structure that has a number average molecular weight of from 8,000 to 30,000.

8. The resin composition according to claim 1, wherein an acid value of the polyester polyurethane resin (A) is from 0.1 mgKOH/g to 20 mgKOH/g.

9. The resin composition according to claim 1, wherein a diol component configuring the polyester polyurethane resin (A) comprises a diol having a side chain.

10. The resin composition according to claim 1, wherein the polyolefin resin (C) is a polypropylene-based resin that is graft-modified with a modifier comprising an α,β-unsaturated carboxylic acid or a derivative thereof, and a content of a graft portion is from 0.1% by mass to 20% by mass with respect to a total mass of the polyolefin resin (C).

11. The resin composition according to claim 1, further comprising a metal filler (E).

12. The resin composition according to claim 11, comprising the metal filler (E) in an amount of from 10 parts by mass to 350 parts by mass with respect to a total amount, of 100 parts by mass, of a resin solid content except for a filler component.

13. The resin composition according to claim 11, wherein the metal filler (E) is a conductive filler.

14. A layered body including a resin composition layer, the layered body comprising:
a resin composition layer that consists of the resin composition according to claim 1; and
a base film that is in contact with at least one surface of the resin composition layer,
wherein the resin composition layer is in a B-stage state.

15. A layered body, comprising a cured layer obtained by curing the resin composition according to claim 1.

16. An electromagnetic wave shielding film, comprising a resin composition layer that consists of the resin composition according to claim 1.
